(19) United States
(12) Patent Application Publication
(10) Pub. No.: US 2002/0163038 A1
(43) Pub. Date: Nov. 7, 2002

(54) Semiconductor device and method for fabricating the same

(75) Inventors: Hoon Chang, Cheongju-shi (KR); Dae Byung Kim, Cheongju-shi (KR)

Correspondence Address: Finnegan, Henderson, Farabow,, Garrett & Dunner, L.L.P., 1300 I Street, N.W., Washington, DC, 20005-3315, US

(73) Assignee: Hynix Semiconductor Inc.

(21) Appl. No.: 10/135,455

(22) Filed: May 1, 2002

(30) Foreign Application Priority Data
May 3, 2001 (KR) P2001-24088

(51) Int. Cl. H01L 29/76; H01L 29/94; H01L 31/062; H01L 31/113

(52) U.S. Cl. 257/338

(57) ABSTRACT

The semiconductor device and the method for fabricating the same includes a trench formed with a predetermined depth in a region of a substrate. A device isolation film is formed as a sidewall type spacers at both sides of the trench. A second conductivity type semiconductor film is formed in the trench. A second conductivity type transistor is formed in first and second regions of the substrate, and a first conductivity type transistor formed in a third region of the substrate.

### CROSS-REFERENCE TO RELATED APPLICATION

This application claims benefit of priority under 35 U.S.C. § 119 to Korean Application Serial No. 2001-24088 filed May 3, 2001, the entire contents of which are incorporated by reference herein.

### FIELD OF THE INVENTION

The present invention relates to semiconductor devices, and more particularly, to semiconductor devices and a methods for fabricating the same that improves isolation characteristics between wells and also improves pattern density by decreasing a design rule.

### BACKGROUND OF THE INVENTION

Generally, the Complementary Metal Oxide Semiconductor (CMOS) consists of a p-type metal oxide semiconductor (PMOS) transistor that has excellent power consumption and an n-type metal oxide semiconductor (NMOS) transistor that may operate at high speed. The NMOS transistor and the PMOS transistor are symmetrical to each other. The CMOS consumes a small amount of power but has drawbacks in that packing density and fabricating process steps are complicated.

A related art method for fabricating a semiconductor device is explained with reference to the accompanying drawings. FIG. 1A and FIG. 1D are cross-sectional views showing a related art method for fabricating a semiconductor device.

As shown in FIG. 1A, p type impurity ions and n type impurity ions are selectively implanted into a predetermined region of a p-type semiconductor substrate 11 by an ion implantation process, and p wells 12 and an n well 13 are respectively formed by drive-in diffusion process.

After p wells 12 and n well 13 are formed, regions where the n well 13 is to be formed is masked by a masking process and then p type impurity ions are implanted into regions where p wells 12 is to be formed. P wells 12 are then masked and n type impurity ions are implanted into a region where n well 13 is to be formed.

Subsequently, a pad oxide film and a nitride film (not shown) are formed on the entire surface of semiconductor substrate I1. The nitride film and the oxide film in an isolation region are selectively removed by photolithography and etching processes.

Then, semiconductor substrate 11 is selectively removed by using the etched nitride film as a mask to form a trench having a predetermined depth. A gap-fill material is deposited on the entire surface of semiconductor substrate 11 including the trench. A device isolation films 14, having a shallow trench isolation (STI) structure in semiconductor substrate 11 corresponding to a boundary between p wells 12 and n well 13, are formed by performing a chemical mechanical polishing (CMP) process. The nitride film and the pad oxide film are then removed.

As shown in FIG. 1 B, an oxide film and polysilicon film (both not shown) are formed sequentially on the entire surface of semiconductor substrate 11 including device isolation film 14. A first photoresist film (not shown) is deposited on the polysilicon film and then selectively patterned by exposure and developing processes, so that a gate region is defined.

Subsequently, the polysilicon film and the oxide film are selectively etched using the patterned first photoresist as a mask to form a gate oxide film 15 and first, second, and third electrodes 16a, 16b, and 16c. The first photoresist film is then removed.

As shown in FIG. 1C, a second photoresist film (not shown) is deposited on the entire surface of semiconductor substrate 11 including first, second, and third gate electrodes 16a, 16b, and 16c. The second photoresist film is then selectively patterned by exposure and developing processes to leave the film only at an upper part of n well 13 region.

Then, n-type lightly doped impurity ions are implanted and drive in diffused into semiconductor substrate 11 using the patterned second photoresist film as a mask, so that an n-type lightly doped impurity regions 17 are formed in a region of p wells 12 at both sides of first and third gate electrodes 16a and 16c. The second photoresist film is then removed.

A third photoresist film (not shown) is deposited on the entire surface of semiconductor substrate 11 including first, second, and third gate electrodes 16a, 16b, and 16c. The third photoresist film is then selectively patterned by exposure and developing processes to leave the film only at the upper part of the p wells 12.

Subsequently, p-type lightly doped impurity ions are implanted and drive-in diffused into semiconductor substrate 11 using the patterned third photoresist film as a mask, so that a p-type lightly doped impurity regions 18 are formed in a region of n well 13 region at both sides of second gate electrode 16b. The third photoresist film is then removed.

As shown in FIG. 1D, an insulating film (not shown), for example, a nitride film, is formed on the entire surface of semiconductor substrate 11 including first, second, and third gate electrodes 16a, 16a, and 16c. The insulating film is then etched back to form gate-insulating sidewalls 19 at both sides of first, second, and third gate electrodes 16a, 16a, and 16c.

Subsequently, a fourth photoresist film (not shown) is deposited on the entire surface of semiconductor substrate 11 including first, second, and third gate electrodes 16a, 16b, and 16c. The fourth photoresist film is then selectively patterned by exposure and developing processes to leave the film only at an upper part of n well 13.

Then, n-type heavily doped impurity ions are implanted and drive-in diffused into semiconductor substrate 11 using the patterned fourth photoresist film as a mask, so that n-type heavily doped impurity regions 20 are formed in a region of p wells 12 at both sides of first and third gate electrodes 16a and 16c. The fourth photoresist film is then removed.

A fifth photoresist film (not shown) is deposited on the entire surface of semiconductor substrate 11 including first, second, and third gate electrodes 16a, 16b, and 16c. The fifth photoresist film is then selectively patterned by exposure and developing processes to leave the film only at an upper part of p wells 12.

Then, p-type heavily doped impurity ions are implanted and drive-in diffused into semiconductor substrate 11 using the patterned fifth photoresist film as a mask, so that a p-type heavily doped impurity regions 21 are formed in a region of n well 13 at both sides of second gate electrode 16b. The fifth photoresist film is then removed.

However, the related art method for fabricating a semiconductor device may have the following drawbacks. Since isolation between wells is not perfect, a minimum design rule related to the wells cannot be effectively reduced. This is disadvantageous for pattern density because active space having a greater area has to be maintained.

Furthermore, with well-known methods, to form an isolation region, complicated processes such as a STI photolithography process, an etching process, a gap-fill process, and a STI CMP process are required. This increases the fabricating cost.

### SUMMARY OF THE INVENTION

Accordingly, the present invention is directed to semiconductor devices and methods for fabricating the same that substantially obviate one or more drawbacks due to limitations and disadvantages of the related art.

The present invention provides semiconductor devices and methods for fabricating the same that reduce cost by a implementing simplified process. The present invention provides semiconductor devices and methods for fabricating the same that maximize isolation characteristics and minimizes a design rule related to the isolation to improve pattern density.

In one aspect consistent with the present invention, as embodied and broadly described herein, a semiconductor device comprising a first conductivity type substrate where first and second regions on which a second conductivity type transistor will be formed and a third region where a first conductivity type transistor will be formed between the first and second regions, a trench formed having a predetermined depth in the third region of the substrate, a device isolation film formed at both sides of the trench in a sidewall type spacers, a second conductivity type semiconductor film formed in the trench; a second conductivity type transistor formed in first and second regions of the first conductivity type substrate, and a first conductivity type transistor formed in the third region of the first conductivity type substrate.

In another aspect consistent with the present invention, a method for fabricating a semiconductor device comprises forming a trench having a predetermined depth in the third region of the first conductivity type substrate, the first conductivity type substrate comprising the first and second regions on which the second conductivity type transistor will be formed and the third region on which the first conductivity type transistor will be formed between the first and second regions, forming an insulating film on an entire surface including the trench and etching back the insulating film to form a device isolation film at both sides of the trench; forming a second conductivity type semiconductor film in the trench, forming a second conductivity type transistor in the first and second regions of the first conductivity type substrate, and forming a first conductivity type transistor in the third region of first conductivity type substrate.

Additional advantages and features of the invention will be set forth in part in the description which follows and in part will become apparent to those having ordinary skill in the art upon examination of the following or may be learned from practice of the invention. The other advantages and features of the invention may be realized and attained by the structure particularly pointed out in the written description and claims hereof as well as the appended drawings.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1A and FIG. 1D illustrate cross-sectional views showing a related art method for fabricating a semiconductor device;

FIGS. 2A and 2B illustrate a structural cross-sectional view showing a semiconductor device according to the present invention; and

FIGS. 3A to 30 illustrate cross-sectional views showing a method for fabricating a semiconductor device according to the present invention.

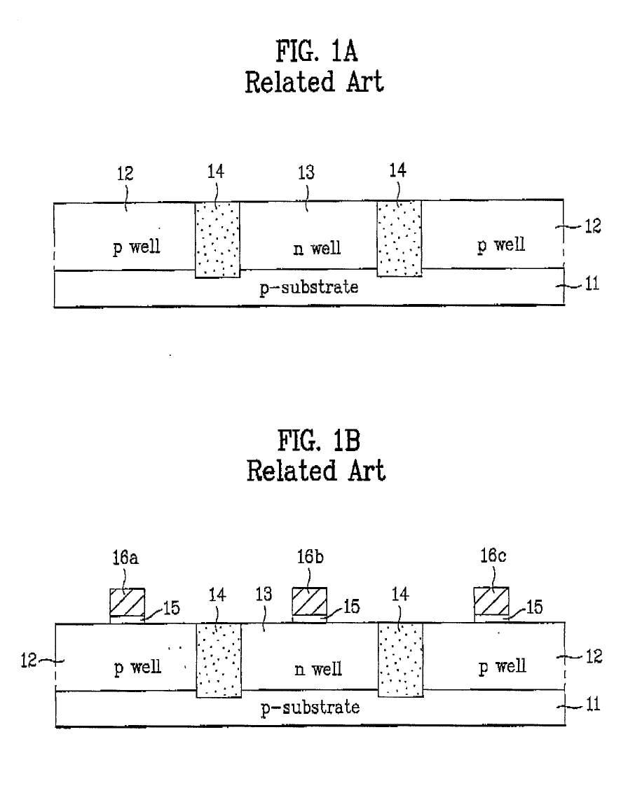

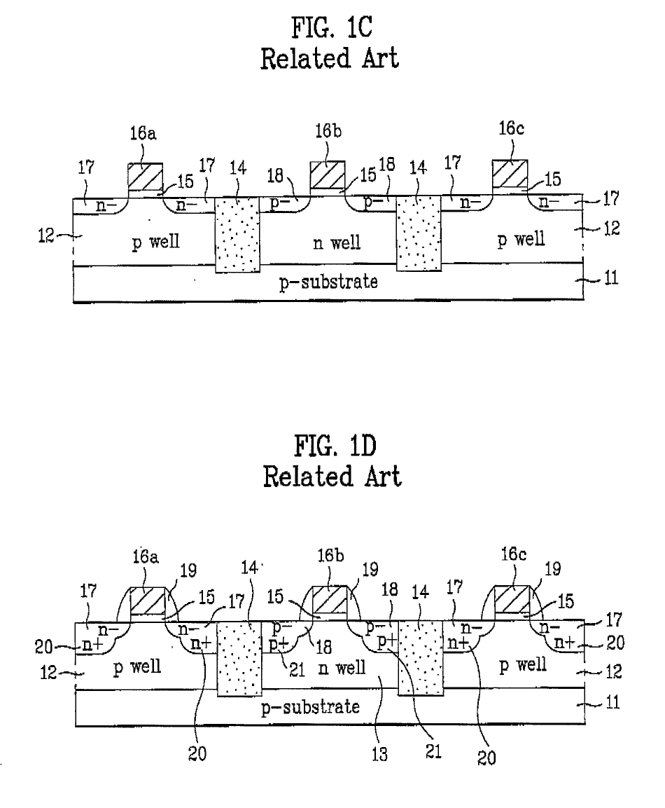

### DESCRIPTION OF THE EMBODIMENTS

Reference will now be made in detail to the preferred embodiments of the present invention, examples of which are illustrated in the accompanying drawings.

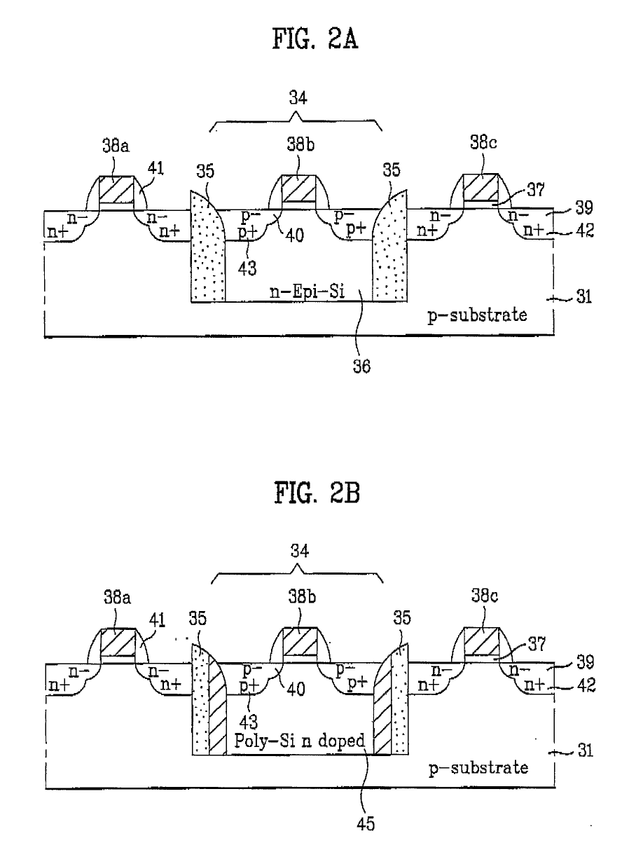

As shown in FIG. 2A, a semiconductor device of the present invention comprises a trench 34 formed having a predetermined depth in a middle part of a p-type semiconductor substrate 31, device isolation films 35 formed as sidewalls at both sides of the trench 34, an n-type epitaxial silicon film 36 formed in trench 34, first, second, and third gate electrodes 38a, 38b, and 38c formed on semiconductor substrate 31 and the epitaxial silicon film 36 at both sides of trench 34 by exposing a gate oxide film 37 therebetween, gate sidewalls 41 formed at both sides of first, second, and third gate electrodes 38a, 38b, and 38c, n-type lightly doped impurity regions 39 and n-type heavily doped impurity regions 42 formed on a surface of substrate 31 at both sides of first and third gate electrodes 38a and 38c and p-type lightly doped impurity regions 40 and a p-type heavily doped impurity regions 43 formed in a surface of epitaxial silicon film 36 at both sides of second gate electrode 38b.

As shown in FIG. 2A, device isolation films 35 are formed in a single structure of an oxide film. As shown in FIG. 2B device isolation films 35 may be formed in a double structure of an oxide film and a nitride film. Also, polysilicon film 45 doped with n-type impurity ions may be used instead of epitaxial silicon film 36. One skilled in the art would realize that any combination of single or double structure device isolation films may be used with either epitaxial silicon films or n-type doped polysilicon films.

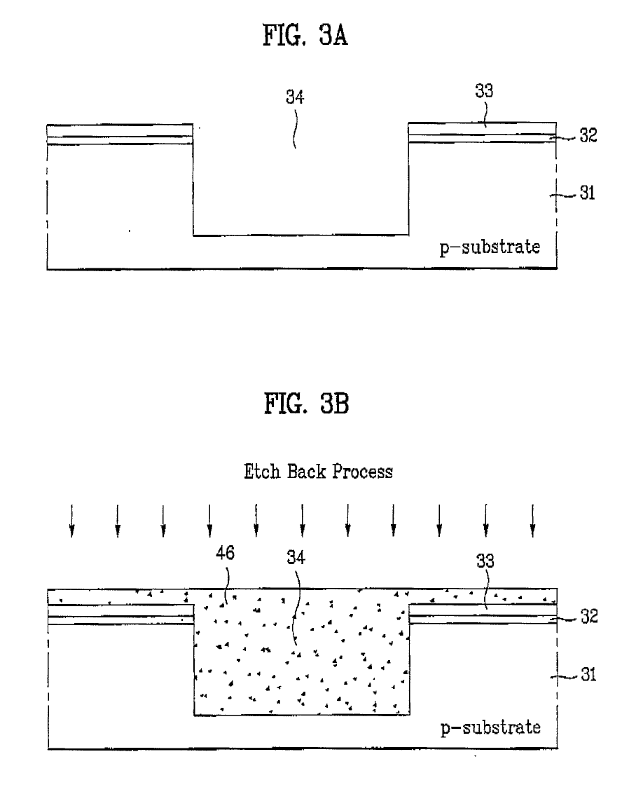

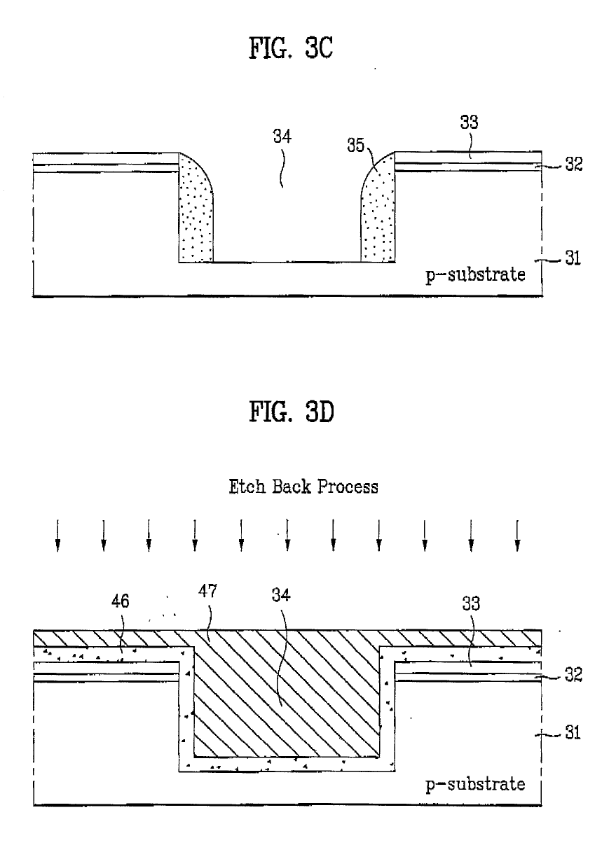

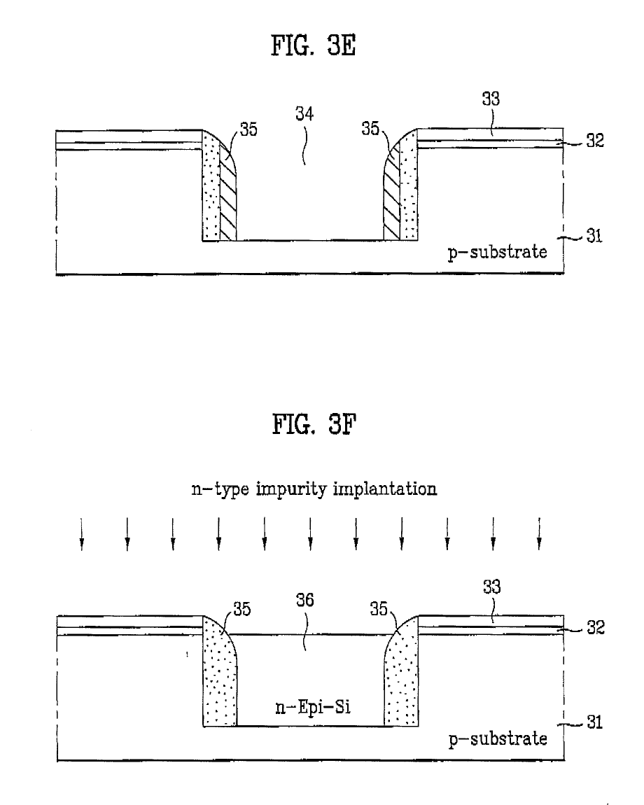

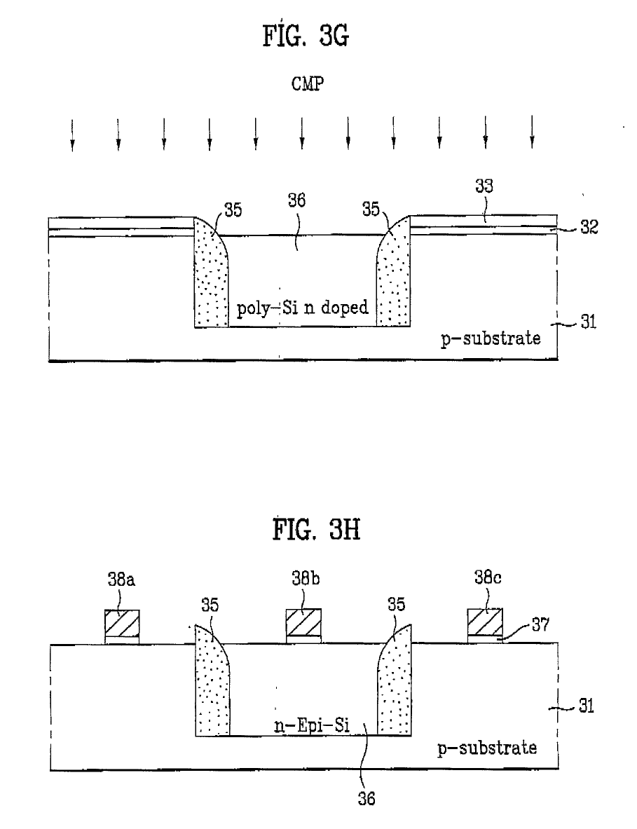

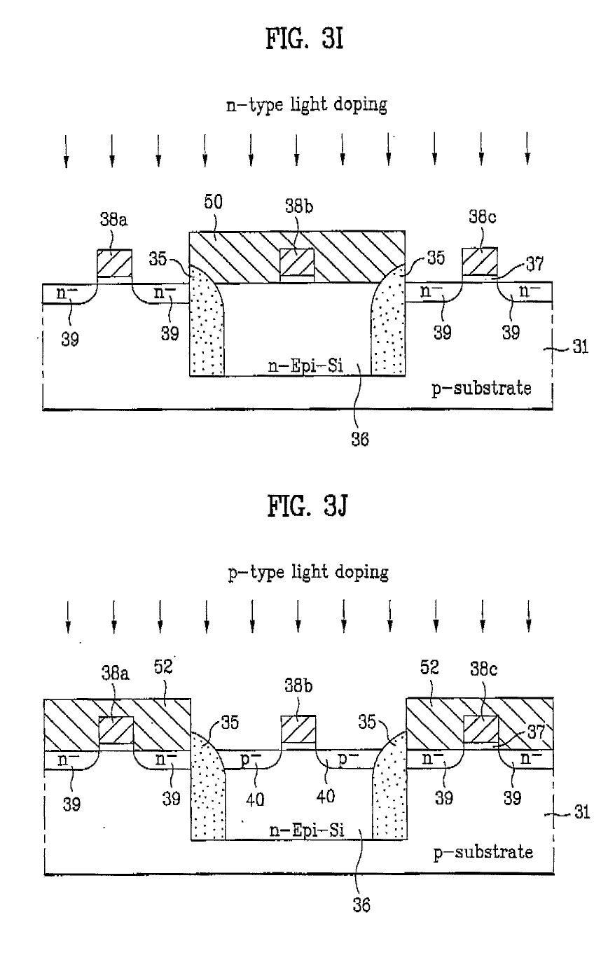

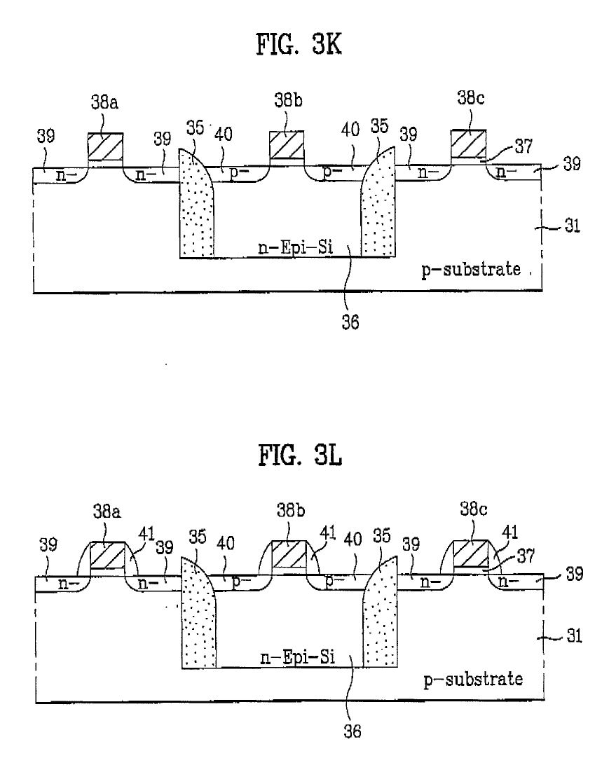

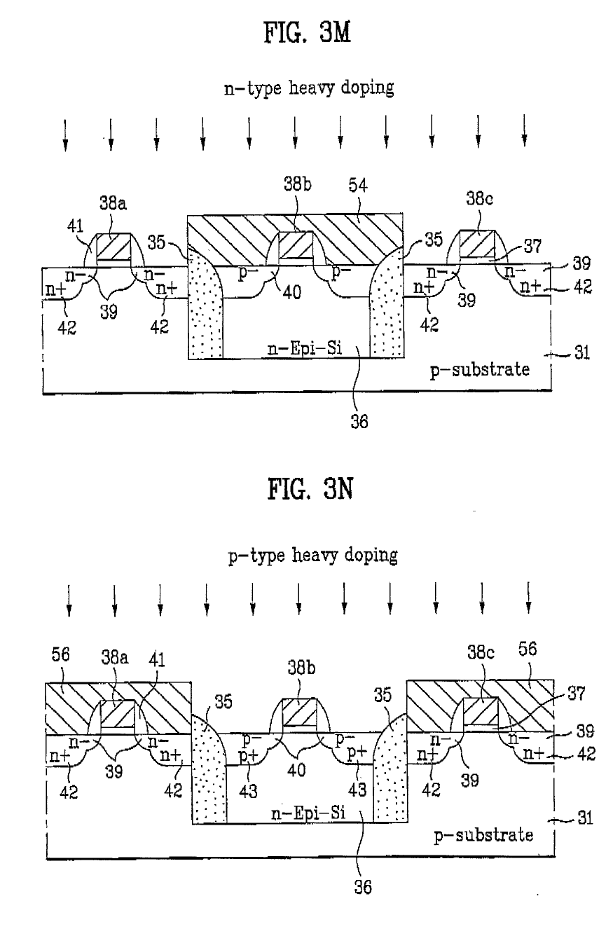

A method for fabricating a semiconductor device according to the present invention is described with reference to FIG. 3A to FIG. 30.

As shown in FIG. 3A, a pad oxide film 32 and a nitride film 33 are formed on p-type semiconductor substrate 31 sequentially. Nitride film 33 and pad oxide film 32 are selectively removed by photolithography and etching processes to partially expose a surface of semiconductor substrate 31.

Then, exposed semiconductor substrate 31 is selectively removed using the selectively removed nitride film 33 and pad oxide film 32 as masks to form trench 34 having to a predetermined depth.

As shown in FIG. 3B, an oxide film 46 is formed on the entire surface of substrate 31 including trench 34. Device isolation films 35, consisting of oxide film sidewalls, are then formed at both sides of trench 34 by performing an etch-back process oxide film 46 formed on the entire surface as shown in FIG. 3C.

Alternatively as shown in FIG. 3D, device isolation films 35 may be formed by depositing an oxide film 46 and nitride film 47. Device isolation films 35, consisting of oxide film and nitride film sidewalls, are then formed at both sides of trench 34 by performing an etch-back process oxide film 46 and nitride film 47 formed on the entire surface as shown in FIG. 3E.

As shown in FIG. 3F, n-type impurity ions are implanted into semiconductor substrate 31 using nitride film 33 and pad oxide film 32 as masks and at the same time n-type epitaxial silicon film 36 is formed within trench 34 by performing an epitaxial process.

Alternatively, n-type epitaxial silicon film 36 may be formed by a CMP process. As shown in FIG. 3G, a polysilicon layer doped with n-type impurity ions is deposited on the entire surface of semiconductor substrate 31 including trench 34 and is then removed by the CMP process to leave the film within trench 34.

As shown in FIG. 3H, pad oxide film 32 and nitride film 33 are removed. An oxide film and a polysilicon film (both not shown) are then formed on the entire surface including the device isolation film 35 in turn. A first photoresist film (not shown) is deposited on the polysilicon film and then selectively patterned by exposure and developing processes, so that a gate region is defined.

Subsequently, the polysilicon film and the oxide film are selectively etched using the patterned first photoresist film as a mask to form gate oxide films 37 and first, second, and third gate electrodes 38a, 38b, and 38c. The first photoresist film is then removed.

As shown in FIG. 31, a second photoresist film 50 is deposited on the entire surface of semiconductor substrate 31 including first, second, and third gate electrodes 38a, 38b, and 38c. Second photoresist film 50 is then selectively patterned by exposure and developing processes to leave the film only at an upper part of epitaxial silicon film 36.

Subsequently, n-type lightly doped impurity ions are implanted and drive in diffused into semiconductor substrate 31 using patterned second photoresist film 50 as a mask, so that n-type lightly doped impurity regions 39 are formed in a region of semiconductor substrate 31 at both sides of the first and third gate electrodes 38a and 38c. Second photoresist film 50 is then removed.

As shown in FIG. 3J, a third photoresist film 52 is deposited on the entire surface of semiconductor substrate 31 including first, second, and third gate electrodes 38a, 38b, and 38c. Third photoresist film 52 is then selectively patterned by exposure and developing processes to leave open only an upper part of epitaxial silicon film 36.

Subsequently, p-type lightly doped impurity ions are implanted and drive-in diffused in epitaxial silicon film 36 using patterned third photoresist film 52 as a mask, so that p-type lightly doped impurity regions 40 are formed in a region of epitaxial silicon film 36 at both sides of second gate electrode 38b. Third photoresist film 52 is then removed leaving the structure as shown in FIG. 3K.

As shown in FIG. 3L, an insulating film (not shown), for example a nitride film, is formed on the entire surface of semiconductor substrate 31 including first, second, and third gate electrodes 38a, 38b, and 38c. The insulating film is then etched-back, so that gate sidewalls 41 are formed at both sides of first, second, and third gate electrodes 38a, 38b, and 38c.

Then as shown in FIG. 3M, a fourth photoresist film 54 is deposited on the entire surface of semiconductor substrate 31 including first, second, and third gate electrodes 38a, 38b, and 38c. Fourth photoresist film 54 is then selectively patterned by exposure and developing processes to leave the film at only an upper part of epitaxial silicon film 36.

Subsequently, n-type heavily doped impurity ions are implanted and drive-in diffused in semiconductor substrate 31 using patterned fourth photoresist film 54 as a mask, so that n-type heavily doped impurity regions 42 are formed in a region of semiconductor substrate 31 at both sides of first and third gate electrodes 38a and 38c. Fourth photoresist film 54 is then removed.

As shown in FIG. 3N, a fifth photoresist film 56 is deposited on the entire surface of semiconductor substrate 31 including first, second, and third gate electrodes 38a, 38b, and 38c. Fifth photoresist film 56 is then selectively patterned by exposure and developing processes to leave open only an upper part of epitaxial silicon film 36.

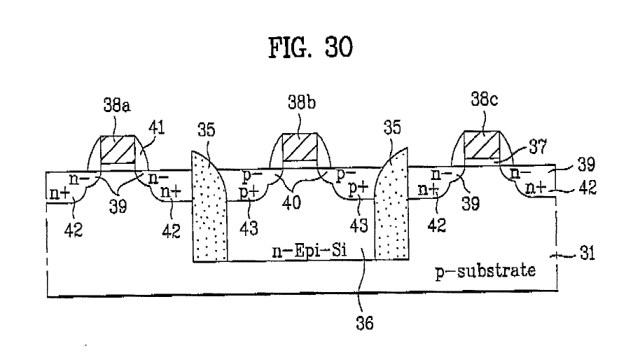

Subsequently, p-type heavily doped impurity ions are implanted and drive-in diffused in epitaxial silicon film 36 using patterned fifth photoresist film 56 as a mask, so that p-type heavily doped impurity regions 43 are formed in a region of epitaxial silicon film 36 at both sides of second gate electrode 38b. Fifth photoresist film 56 is then removed leaving the structure as shown in FIG. 30.

As described above, semiconductor devices and methods for fabricating the same according to the present invention have the following advantages. First, isolation characteristics may be improved by forming isolation areas between wells as sidewall type spacers so p wells 40, 43 uses p type substrate 31 and n wells 39, 42 uses n-type epitaxial silicon film 36.

Second, isolation areas 35 are formed at both sides of trench 34 as a sidewall spacer type, so that a design rule related to isolation decreases, thereby improving the pattern density. Finally, since the processes may be reduced, simplified processes and reduced cost may be obtained.

The forgoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. A semiconductor device comprising:
a first conductivity type substrate comprising first and second regions on which a second conductivity type transistor will be formed and a third region on which a first conductivity type transistor will be formed between the first and second regions;
a trench formed to a predetermined depth in the third region of the first conductivity type substrate;
a device isolation film formed at both sides of the trench as sidewall type spacers;
a second conductivity type semiconductor film formed in the trench;
a second conductivity type transistor formed in the first and second regions of the first conductivity type substrate; and
a first conductivity type transistor formed in the third region of the first conductivity type substrate.

2. A semiconductor device as set forth in claim 1, wherein the device isolation film comprises either an oxide film or both an oxide film and a nitride film.

3. A semiconductor device as set forth in claim 1, the second conductivity type semiconductor film is either an epitaxial silicon film or a polysilicon film doped with a second conductivity type impurity ion.

4. A method for fabricating a semiconductor device comprising:
forming a trench having a predetermined depth in a third region of a first conductivity type substrate, the first conductivity type substrate comprising first and second regions on which a second conductivity type transistor will be formed, and a third region on which a first conductivity type transistor will be formed between the first and second regions;
forming an insulating film on an entire surface including the trench and etching-back the insulating film to form a device isolation film at both sides of the trench;
forming a second conductivity type semiconductor film in the trench;
forming a second conductivity type transistor in the first and second regions of the first conductivity type substrate; and
forming a first conductivity type transistor in the third region of the first conductivity type substrate.

5. A method for fabricating a semiconductor device as set forth in claim 4, wherein the insulating film is formed in a single structure of an oxide film or in a double structure of an oxide film and a nitride film.

6. A method for fabricating a semiconductor device as set forth in claim 4, wherein the second conductivity type semiconductor film is formed by epitaxial growth while implanting second conductivity type impurity ions into the first conductivity type substrate wherein the first and second regions are masked.

7. A method for fabricating a semiconductor device as set forth in claim 4, the second conductivity type semiconductor film is flattened by a CMP process after a polysilicon doped with second conductivity type impurity ion is deposited on the entire surface of the first conductivity type semiconductor substrate including the trench.
